(19) United States
(12) Patent Application Publication
(10) Pub. No.: US 2026/0038609 A1
(43) Pub. Date: Feb. 5, 2026

(54) STORAGE DEVICE INCLUDING MEMORY DEVICE AND MEMORY CONTROLLER AND OPERATING METHOD OF THE STORAGE DEVICE

(71) Applicant: SAMSUNG ELECTRONICS CO., LTD., Suwon-si (KR)

(72) Inventor: Eun Chu Oh, Suwon-si (KR)

(73) Assignee: SAMSUNG ELECTRONICS CO., LTD., Suwon-si (KR)

(21) Appl. No.: 19/252,915

(22) Filed: Jun. 27, 2025

(30) Foreign Application Priority Data
Aug. 5, 2024 (KR) 10-2024-0104142

(51) Int. Cl. G11C 16/34; G11C 16/08; G11C 16/26; G11C 16/32

(52) U.S. Cl. CPC G11C 16/3418; G11C 16/08; G11C 16/26; G11C 16/32

(57) ABSTRACT

A storage device including a nonvolatile memory device and a memory controller and an operating method of the storage device are provided. The nonvolatile memory device includes a plurality of memory areas each including one or more memory cells, one or more temperature sensors configured to generate first temperature information by measuring at least one temperature of at least one memory area from among the plurality of memory areas periodically between a first time point and a second time point, and a buffer configured to store the first temperature information.

### CROSS-REFERENCE TO RELATED APPLICATION

This application is based on and claims priority under 35 U.S.C. § 119 to Korean Patent Application No. 10-2024-0104142, filed on Aug. 5, 2024, in the Korean Intellectual Property Office, the disclosure of which is herein incorporated by reference in its entirety.

### BACKGROUND

One or more example embodiments of the disclosure relate to a storage device including a memory device and a memory controller and an operating method of the storage device, and more particularly, to a storage device for adjusting a period of reclaiming, garbage collection, and/or trimming of a nonvolatile memory device according to a temperature and an operating method of the storage device.

A memory device may store data in response to a write request and may output the stored data in response to a read request. Memory devices may be classified into a volatile memory device such as a dynamic random-access memory (DRAM), a static random-access memory (SRAM), etc. that loses data stored therein when a power supply thereto is blocked, and a nonvolatile memory device such as a flash memory device, a phase-change random-access memory (PRAM), a magnetic random-access memory (MRAM), a resistive random-access memory (RRAM), etc. that retains data stored therein even when a power supply thereto is blocked. In the case of the nonvolatile memory device, in order to increase a memory efficiency and manage reusability of resources, operations of reclaiming, garbage collection, trimming, etc. may be performed. However, in determining periods of these operations, when retention of a memory device according to a temperature of the memory device is not considered, there may be problems such as performance deterioration, increased power consumption, and/or an increased wear amplification factor (WAF), etc., due to unnecessary reclaiming and/or garbage collection.

### SUMMARY

One or more example embodiments of the disclosure provide an operating method of a storage device that may improve an efficiency of reclaim, garbage collection, and trim operations, etc. performed on a nonvolatile memory, by taking into account data retention in a memory device according to a temperature.

According to an aspect of an example embodiment of the disclosure, there is provided a storage device including: a nonvolatile memory device including a plurality of memory areas, each memory area including one or more memory cells; one or more temperature sensors configured to generate first temperature information by periodically measuring, in a time period between a first time point and a second time point, at least one temperature of at least one memory area from among the plurality of memory areas; and a buffer configured to store the first temperature information; and a memory controller configured to: obtain the first temperature information by transmitting, to the nonvolatile memory device, a first command for requesting the first temperature information; determine an equivalent temperature, based on at least one of a temperature change amount and a highest temperature of the at least one memory area measured in the time period between the first time point and the second time point; and adjust, based on the equivalent temperature, at least one of a period of a reclaim operation, a period of a garbage collection operation, and a period of a trim operation on the at least one memory area.

According to another aspect of the disclosure, there is provided an operating method of a storage device including a nonvolatile memory device and a memory controller, the nonvolatile memory device including a plurality of memory areas and at least one temperature sensor, the operating method including: generating, by the at least one temperature sensor, first temperature information by periodically measuring, in a time period between a first time point and a second time point, at least one temperature of at least one memory area from among the plurality of memory areas; storing the first temperature information in a buffer of the nonvolatile memory device; transmitting, by the memory controller, a first command for requesting the first temperature information to the nonvolatile memory device; in response to the first command received from the memory controller, transmitting, by the nonvolatile memory device, the first temperature information to the memory controller; comparing, by the memory controller, a temperature change amount of the at least one memory area in the time period between the first time point and the second time point with a threshold value; based on the temperature change amount being greater than the threshold value, determining a weighted average of the at least one temperature of the at least one memory area measured in the time period between the first time point and the second time point as an equivalent temperature, according to a predetermined temperature calculation function; based on the temperature change amount being equal to or less than the threshold value, determining a highest temperature of the at least one memory area measured in the time period between the first time point and the second time point as the equivalent temperature; and adjusting, by the memory controller, at least one of a period of a reclaim operation, a period of a garbage collection operation, and a period of a trim operation on the at least one memory area, based on the equivalent temperature.

According to another aspect of the disclosure, there is provided an operating method of a storage device including a nonvolatile memory device and a memory controller, the nonvolatile memory device including a plurality of memory areas and at least one temperature sensor, the operating method including: transmitting, by the memory controller, a command for instructing a write operation, a read operation, or an erase operation together with a temperature measurement operation, to the nonvolatile memory device; in response to the command for instructing the write operation, the read operation, or the erase operation, performing, by the nonvolatile memory device, the write operation, the read operation, or the erase operation on a first memory area from among the plurality of memory areas; generating, by the at least one temperature sensor, first temperature information by starting periodic temperature measurement on the first memory area; and generating, by the at least one temperature sensor, second temperature information by measuring a temperature of the first memory area while the write operation, the read operation, or the erase operation is performed on the first memory area.

### BRIEF DESCRIPTION OF DRAWINGS

Example embodiments will be more clearly understood from the following detailed description taken in conjunction with the accompanying drawings in which:

FIG. 1 is a block diagram of a storage system according to one or more embodiments;

FIG. 2 is a block diagram of a nonvolatile memory device according to one or more embodiments;

FIG. 3 is a block diagram of a storage device according to one or more embodiments;

FIG. 4 is a timing diagram of an operation of a storage device according to one or more embodiments;

FIG. 5 is a table showing an example of first temperature information according to one or more embodiments;

FIGS. 6 to 9 are flowcharts of an operating method of a storage device, according to embodiments;

FIG. 10 is a table showing an example of second temperature information according to one or more embodiments;

FIG. 11 is a flowchart of an operating method of a resource management module, according to one or more embodiments;

FIG. 12 is a table showing an example of a retention table according to one or more embodiments;

FIG. 13 is a diagram of an example in which a memory controller determines a priority order of a plurality of memory areas, according to one or more embodiments;

FIG. 14 is a block diagram of a storage system according to one or more other embodiments; and

FIG. 15 is a block diagram of a user system in which a storage device is implemented, according to one or more embodiments.

### DETAILED DESCRIPTION

Hereinafter, one or more example embodiments are described in detail with reference to the accompanying drawings.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

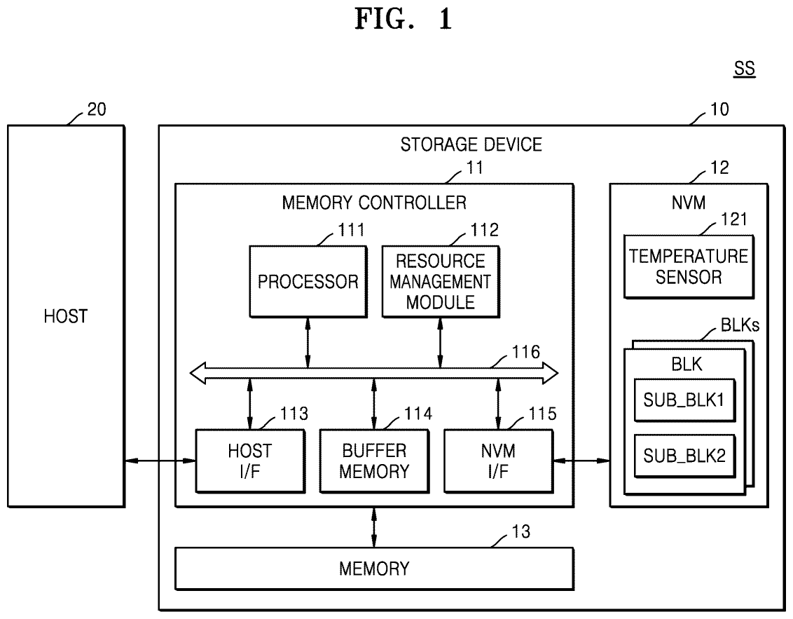

FIG. 1 is a block diagram of a host-storage device system SS according to one or more embodiments.

Referring to FIG. 1, the host-storage device system SS may include a storage device 10 and a host 20, wherein the storage device 10 may include a memory controller 11, a nonvolatile memory device (that is, an NVM device) 12, and a memory device 13.

The nonvolatile memory device 12 may include one or more temperature sensors 121 and a plurality of memory blocks BLKs. The nonvolatile memory device 12 may operate in response to control by the memory controller 11. Operations of the nonvolatile memory device 12 may include, for example, a read operation, a write operation (or also referred to as a program operation), an erase operation, etc.

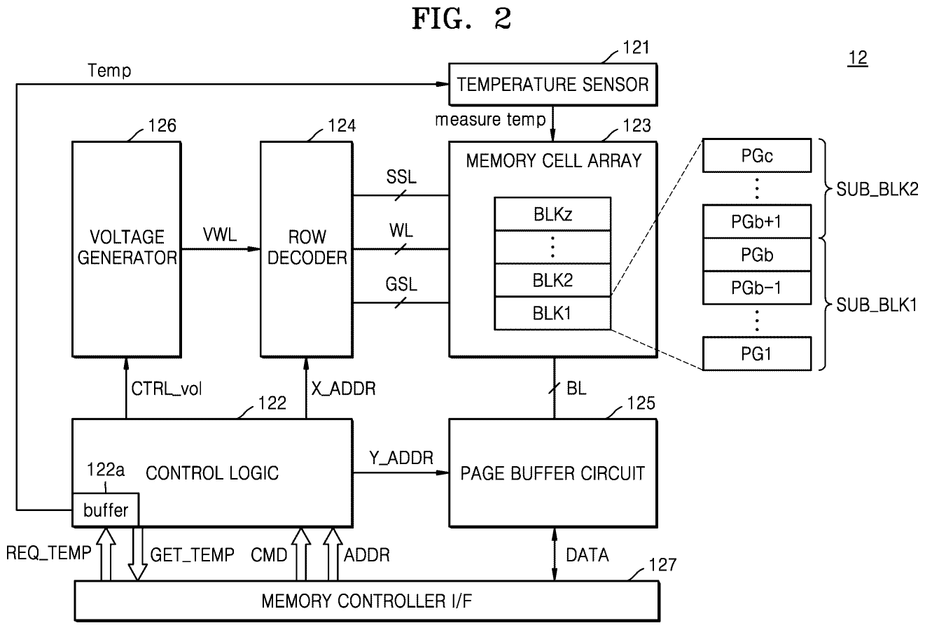

The nonvolatile memory device 12 may include a memory cell array (e.g., 123 in FIG. 2) including a plurality of memory cells storing data. For example, the memory cell array may include the plurality of memory blocks BLKs. Each of the plurality of memory blocks BLK may include a plurality of sub-blocks having different block sizes, for example, sub-blocks SUB_BLK1 and SUB_BLK2. Each memory block BLK may include a plurality of pages (e.g., PG in FIG. 2). The memory block or the sub-block may correspond to an erase unit and the page may correspond to a program (or write) unit and a read unit, but the disclosure is not limited thereto. The erase unit, the write unit, and the read unit may be changed to a page unit, a word line unit, a sub-block unit, a super-block unit, etc.

The one or more temperature sensors 121 may be configured to measure a temperature of the nonvolatile memory device 12. According to one or more embodiments, the one or more temperature sensors 121 may be configured to measure a temperature of the memory cell array (e.g., 123 in FIG. 2). According to another embodiment, the memory cell array 123 may include a plurality of memory areas each including one or more memory cells, and each of the one or more temperature sensors 121 may measure a temperature of a corresponding memory area. According to another embodiment, the one or more temperature sensors 121 may measure a temperature of one or more memory areas from among the plurality of memory areas. For example, the one or more temperature sensors 121 may measure a temperature of a memory area on which a read, write, or erase operation is performed. A temperature measurement unit of the one or more temperature sensors 121, that is, the memory area, may include a block, a super block, a plurality of word lines, a single word line, a page, etc. A method used by the one or more temperature sensors 121 to measure the temperature will be described later with reference to FIGS. 2 to 9.

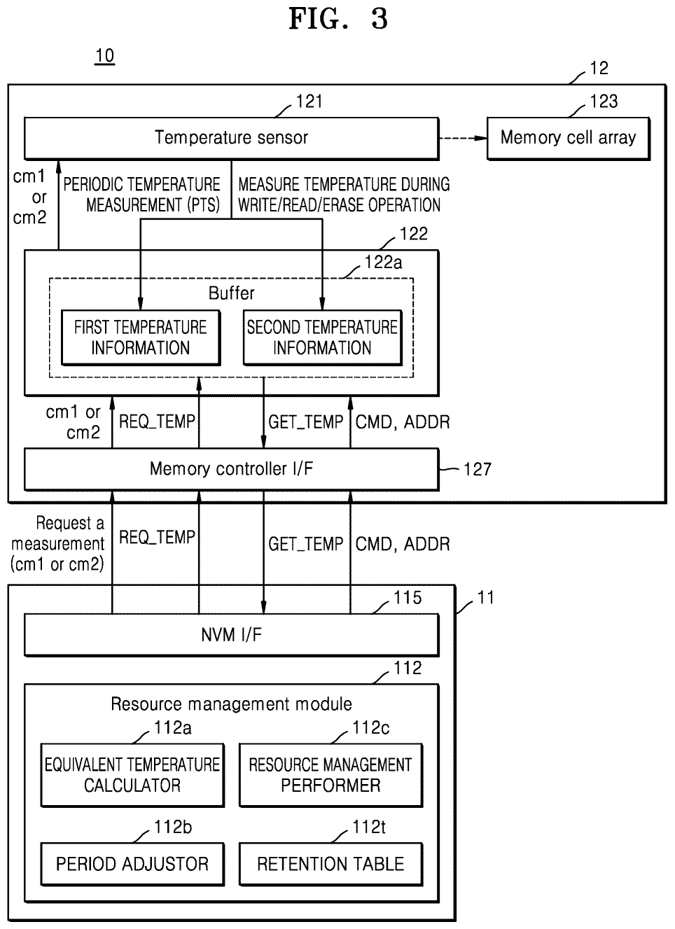

The temperature measured by the one or more temperature sensors 121 may be stored in an additional storage area (for example, one or more registers of the one or more temperature sensors 121, a buffer (e.g., 122a in FIG. 2) of a control logic (e.g., 122 in FIG. 2), a static random-access memory, etc.). The memory controller 11 may access the additional storage area and obtain temperature information. According to another embodiment, the memory controller 11 may transmit a command (or referred to as a temperature check command) for requesting the temperature measured by the one or more temperature sensors 121 to the nonvolatile memory device 12, and the nonvolatile memory device 12 may transmit the measured temperature to the memory controller 11 in response to the command. Aspects about this operation will be described later with reference to FIGS. 3, 4, and 6 to 9.

The memory controller 11 may communicate with the nonvolatile memory device 12 and may control reclaim, garbage collection, trim operations, etc. on the nonvolatile memory device 12. In detail, by taking into account retention of data based on the temperature, the memory controller 11 may determine and/or adjust a period of reclaim, garbage collection, and/or trim operations, etc. on the nonvolatile memory device 12. Thus, the memory controller 11 may reduce a frequency of the reclaim, garbage collection, and/or trim operations, etc. Hereinafter, detailed configurations and operations of the memory controller 11 are described in detail.

The memory controller 11 may include a processor 111, a resource management module 112, a host interface 113, a buffer memory 114, and a nonvolatile memory interface 115. The processor 111, the resource management module 112, the host interface 113, the buffer memory 114, and the nonvolatile memory interface 115 may communicate with one another through a bus 116. The processor 111 may include a central processing unit (CPU), a microprocessor, etc. and may control overall operations of the memory controller 11. According to one or more embodiments, the processor 111 may be realized as a multi-core processor, for example, a dual-core processor or a quad-core processor. The buffer memory 114 may temporarily store data which is to be written to the nonvolatile memory device 12 or data which is to be read from the nonvolatile memory device 12. While the buffer memory 114 may be a component that is provided in the memory controller 11, the buffer memory 114 may also be arranged outside the memory controller 11. For example, the memory controller 11 may further include a buffer memory manager or a buffer memory interface configured to communicate with the buffer memory 114.

According to one or more embodiments, the resource management module 112 may control the reclaim, garbage collection, and trim operations, etc. on the nonvolatile memory device 12. The resource management module 112 may determine and/or adjust, based on the temperature of the nonvolatile memory device 12 measured by the one or more temperature sensors 121, the period of the reclaim, garbage collection, and/or trim operations, etc. on the nonvolatile memory device 12, and thus, may increase, maintain, or reduce the frequency of the reclaim, garbage collection, and/or trim operations, etc. It is illustrated that the resource management module 112 is provided in the memory controller 11. However, the disclosure is not limited thereto, and the resource management module 112 may be provided in the nonvolatile memory device 12. Detailed configurations and operations of the resource management module 112 are described later with reference to FIGS. 3, 4, and 6 to 9.

According to one or more embodiments, the resource management module 112 may be realized as software, firmware, and/or hardware. According to one or more embodiments, the resource management module 112 may be realized as software. The memory controller 11 may further include a working memory on which the resource management module 112 is loaded. Also, the processor 111 may be configured to execute the resource management module 112 to control the reclaim, garbage collection, and trim operations, etc. on the nonvolatile memory device 12. For example, the working memory may be realized as a nonvolatile memory such as a static random-access memory (SRAM), a dynamic random-access memory (DRAM), etc., or a nonvolatile memory such as a phase-change random-access memory (PRAM), etc.

According to one or more embodiments, the resource management module 112 may be realized on a flash translation layer (FTL). The memory controller 11 may further include a working memory on which the FTL is loaded. Also, the processor 111 may be configured to execute the FTL to control the reclaim, garbage collection, and/or trim operations, etc. on the nonvolatile memory device 12. Here, the processor 111 may further be configured to execute the FTL to control data write and read operations performed on the nonvolatile memory device 12. Also, the FTL may perform various functions, such as address mapping, wear-leveling, etc. The address mapping may be an operation of changing a logic address received from the host 20 to a physical address actually used to store data in the nonvolatile memory device 12. The wear-leveling may be a technique for preventing inordinate deterioration of a certain block by allowing the blocks BLKs in the nonvolatile memory device 12 to be evenly used and, for example, may be realized by a firmware technique of balancing erase counts of physical blocks.

The host interface 113 may transmit and receive a packet to and from the host 20. The packet transmitted from the host 20 to the host interface 113 may include a command, data to be written to the nonvolatile memory device 12, or the like, and the packet transmitted from the host interface 113 to the host 20 may include a response to a command, data read from the nonvolatile memory device 12, or the like. The nonvolatile memory interface 115 may transmit the data to be written to the nonvolatile memory device 12 to the nonvolatile memory device 12 or may receive the data read from the nonvolatile memory device 12. The nonvolatile memory interface 115 may be realized to comply with standard rules, such as Toggle or an open NAND flash interface (ONFI).

The storage device 10 may include a storage medium configured to store data in response to a request by the host 20. For example, the storage device 10 may include at least one of a solid state drive (SSD), an embedded memory, and a detachable external memory. When the storage device 10 is an SSD, the storage device 10 may comply with the nonvolatile memory express (NVMe) standards. When the storage device 10 is an embedded memory or an external memory, the storage device 10 may comply with the universal flash storage (UFS) standards or the embedded multi-media card (eMMC) standards. Each of the host 20 and the storage device 10 may generate a packet according to an implemented standard protocol and may transmit the packet.

The memory device 13 may include a volatile memory device, such as a DRAM, an SRAM, etc.

According to one or more embodiments, the host 20 may include a host controller and a host memory. The host controller may manage an operation of storing data of a buffer area of the host memory in the nonvolatile memory device 12 or an operation of storing data of the nonvolatile memory device 12 in the buffer area. The host memory may function as a buffer memory to temporarily store data to be transmitted to the storage device 10 and/or data transmitted from the storage device 10.

The memory controller 11 may receive a command from an external device (for example, the host 20) and based on the received command, may perform or control read, write, and erase operations, etc. on the nonvolatile memory device 12 and the memory device 13 (for example, the volatile/nonvolatile memory) included in the storage device 10. When the storage device 10 performs a read, write, or erase operation on the non-volatile memory device 12 and the memory device 13, temperatures of the nonvolatile memory device 12 and the memory device 13 may be changed. Also, even when a read, write, or erase operation is not performed, the temperatures of the nonvolatile memory device 12 and the memory device 13 may be changed according to a change of temperature in the ambient environment. When the temperature of the nonvolatile memory device 12 increases, a retention period, which is a period during which data may be retained in the nonvolatile memory device 12, may be reduced. In contrast, when the temperature of the nonvolatile memory device 12 decreases, the retention period may increase. Thus, it may be desirable that the resource management module 112 adjusts the periods of reclaim, garbage collection, and trim operations, etc. on the nonvolatile memory device 12, based on the temperature and the retention period of the nonvolatile memory device 12 measured by the one or more temperature sensors 121. For example, when the temperature of the nonvolatile memory device 12 is higher than a predetermined temperature, the periods of the reclaim, garbage collection, and trim operations, etc. may be reduced, and when the temperature of the nonvolatile memory device 12 is lower than the predetermined temperature, the periods of the reclaim, garbage collection, and trim operations, etc. may be increased.

FIG. 2 is a block diagram of a nonvolatile memory device 12 according to one or more embodiments.

Referring to FIG. 2, the nonvolatile memory device 12 may include one or more temperature sensors 121, a control logic 122, a memory cell array 123, a row decoder 124, a page buffer circuit 125, a voltage generator 126, and a memory controller interface 127. The nonvolatile memory device 12 may correspond to the nonvolatile memory device 12 of FIG. 1, according to one or more embodiments.

In the memory cell array 123, a plurality of word lines WL, a plurality of bit lines BL, and a plurality of memory cells may be arranged. For example, the plurality of memory cells may include nonvolatile memory cells, and may include nonvolatile memory cells having a vertical channel structure. Each of the plurality of memory cells included in the memory cell array 123 may store at least 1-bit data. For example, each of the plurality of memory cells included in the memory cell array 123 may be a single-level cell (SLC) configured to store 1-bit data. As another example, each memory cell may be a multi-level cell (MLC) configured to store 2-bit data. As another example, each memory cell may be a triple-level cell (TLC) configured to store 3-bit data. As another example, each memory cell may be a quad-level cell (QLC) configured to store 4-bit data. As another example, the memory cell array 123 may include a plurality of memory cells each configured to store data having 5 or greater bits.

The memory cell array 123 may include a plurality of memory blocks BLK1 to BLKz (z is a positive integer). Each of the plurality of memory blocks BLK1 to BLKz may include a plurality of pages PG1 to PGc (c is a positive integer). Each of the plurality of memory blocks BLK1 to BLkz may include the plurality of pages PG1 to PGc corresponding to the plurality of word lines WL and a plurality of strings corresponding to the plurality of bit lines BL. In each of the memory blocks BLK1 to BLKz, the plurality of word lines WL and the plurality of bit lines BL may be arranged to cross each other. For example, each of the plurality of word lines WL may extend in a row direction, and each of the plurality of bit lines BL may extend in a column direction. In other words, the plurality of word lines WL may be arranged in the column direction and the plurality of bit liens BL may be arranged in the row direction. As another example, each of the plurality of word lines WL may extend in the column direction, and each of the plurality of bit lines BL may extend in the row direction. In other words, the plurality of word lines WL may be arranged in the row direction and the plurality of bit liens BL may be arranged in the column direction. A memory cell may be defined to be electrically connected to one of the plurality of word lines WL and one of the plurality of bit lines BL. A transistor may be arranged in each memory cell.

According to one or more embodiments, some of the plurality of pages PG1 to PGc (e.g., PG1 to PGb) may be included in a first sub-block SUB_BLK1, and the others (e.g., PGb+1 to PBc) may be included in a second sub-block SUB_BLK2. For example, the memory block or the sub-block may be an erase unit and the page may be a write unit and a read unit.

The memory cell array 123 may be electrically connected to the page buffer circuit 125 through the plurality of bit lines BL and electrically connected to the row decoder 124 through the plurality of word lines WL, string selection lines SSL, and ground selection lines GSL.

The one or more temperature sensors 121 may measure the temperature of the nonvolatile memory device 12. According to one or more embodiments, the one or more temperature sensors 121 may measure the temperature of the memory cell array 123. According to one or more embodiments, the memory cell array 123 may be divided into a plurality of memory areas each including one or more memory cells, and each of the one or more temperature sensors 121 may measure a temperature of a corresponding memory area among the plurality of memory areas. For example, when the memory cell array 123 includes n (n is a natural number that is 1 or greater) memory areas, each of n temperature sensors 121 may measure a temperature of a corresponding memory area. A unit of the memory area of which temperature is to be measured by a corresponding temperature sensor may correspond to one of a block BLK, a super block, a sub-block SUB_BLK, a plurality of word lines WLs, a single word line WL, and a page PG. Aspects with respect to a method, performed by the one or more temperature sensors 121, of measuring the temperature of the plurality of memory areas, will be described in detail later with reference to FIGS. 3 to 10.

Information on the temperature measured by the one or more temperature sensors 121 may be stored in an additional storage. For example, the temperature information measured by the one or more temperature sensors 121 may be stored in one or more registers of the one or more temperature sensors 121, a buffer 122a of the control logic 122, or an SRAM.

According to one or more embodiments, the control logic 122 of the nonvolatile memory device 12 may receive a command REQ_TEMP for requesting the temperature information measured by the one or more temperature sensors 121, from the memory controller (e.g., 11 in FIG. 1). According to one or more embodiments, the command REQ_TEMP may be a command (or referred to as a temperature check command) for requesting a report of the temperature information stored in the buffer 122a and may correspond to a get feature command defined in NVMe standard specifications. In detail, the command for requesting the temperature information may be generated by using a “reserved” field(s) in a get feature command format.

In response to the command REQ_TEMP, the control logic 122 may transmit temperature information GET_TEMP stored in the buffer 122a to the memory controller 11 through the memory controller interface 127.

The control logic 122 may control overall operations in the nonvolatile memory device 12. The control logic 122 may output various control signals in response to a command CMD and/or an address ADDR received from the memory controller (e.g., 11 in FIG. 1) through the memory controller interface 127. For example, the control logic 122 may output a voltage control signal CTRL_vol, a row address X_ADDR, and a column address Y_ADDR. The voltage generator 126 may generate, based on the voltage control signal CTRL_vol, various kinds of voltages for performing write, read, and erase operations. For example, the voltage generator 126 may generate a program (or write) voltage, a read voltage, a program verify voltage, an erase voltage, etc. as a word line voltage VWL.

The row decoder 124 may select one of the plurality of word lines WL in response to the row address X_ADDR and may select one of the plurality of string selection lines SSL. For example, during a program operation, the row decoder 124 may apply a program voltage and a program verify voltage to the selected word line, and during a read operation, the row decoder 124 may apply a read voltage to the selected word line. The page buffer circuit 125 may select at least one bit line from among the plurality of bit lines BL in response to the column address Y_ADDR. The page buffer circuit 125 may operate as a write driver or a sense amplifier according to an operation mode.

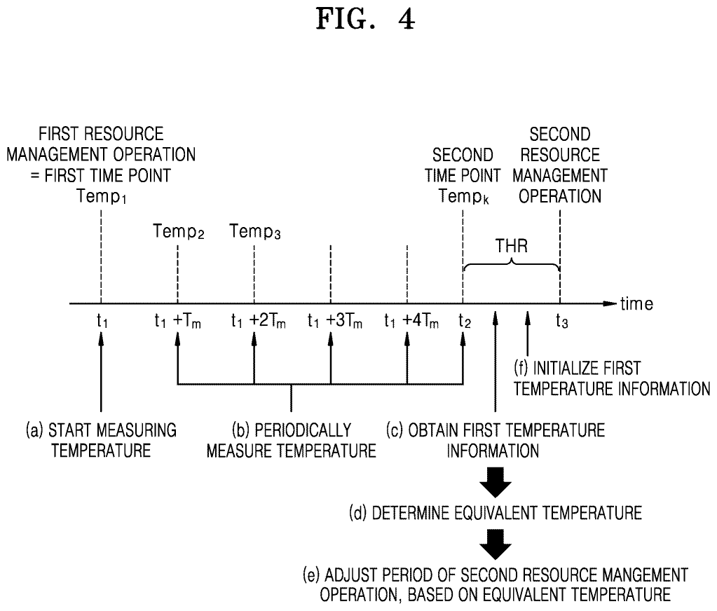

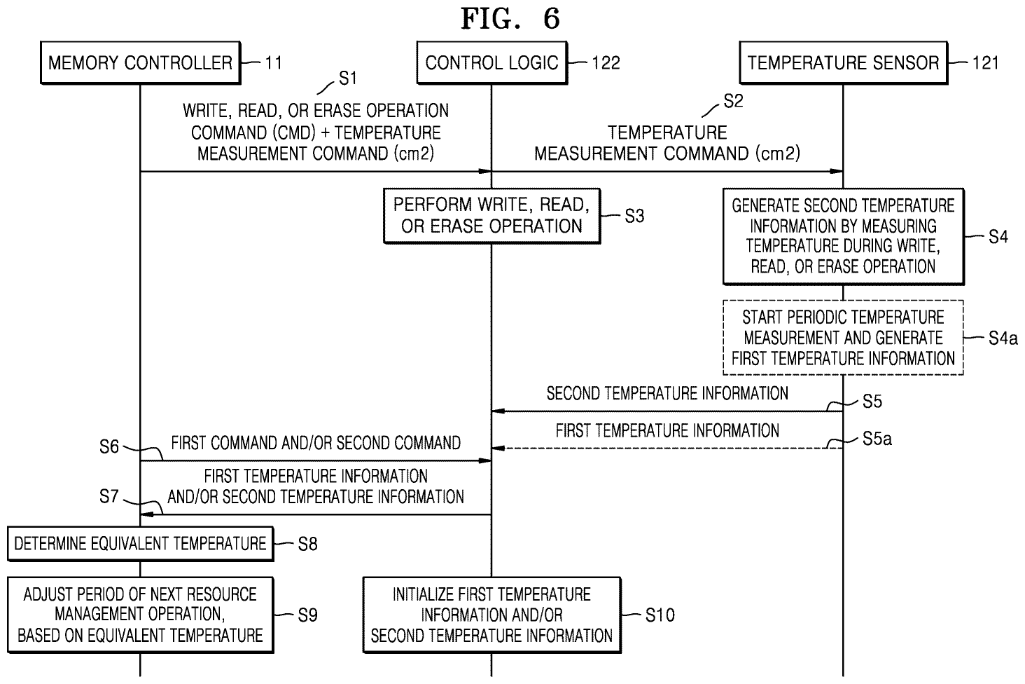

FIG. 3 is a block diagram of a storage device 10 according to one or more embodiments. FIG. 4 is a timing diagram of an operation of the storage device 10 according to one or more embodiments. FIGS. 6 to 9 are flowcharts of an operating method of the storage device 10, according to embodiments.

Referring to FIG. 3, the storage device 10 may include the memory controller 11 and the nonvolatile memory device 12 and may correspond to the storage device 10 of FIG. 1, according to one or more embodiments. An operating method of the nonvolatile memory device 12 of FIG. 3 may correspond to the operating method of the nonvolatile memory device 12 of FIG. 2, according to one or more embodiments. Hereinafter, the same descriptions between the embodiments may be omitted.

The one or more temperature sensors 121 may periodically measure the temperature of the nonvolatile memory device 12, to sense a temperature change in the nonvolatile memory device 12 according to a temperature change in an ambient environment. In other words, the one or more temperature sensors 121 may perform periodic temperature sensing (PTS). Additionally or alternatively, the one or more temperature sensors 121 may sense the temperature change in the nonvolatile memory device 12 by measuring the temperature of the nonvolatile memory device 12 when a read, write, or erase operation is performed on the nonvolatile memory device 12. In other words, the one or more temperature sensors 121 may perform operation temperature sensing (OTS).

Hereinafter, by referring to FIGS. 3 and 4, a PTS method performed by the one or more temperature sensors 121 is described.

The one or more temperature sensors 121 may measure the temperature of at least one memory area from among the plurality of memory areas of the memory cell array 123, periodically between a first time point t₁ and a second time point t₂, and may generate first temperature information (operations (a) and (b)). As described above, the temperature measurement unit of the one or more temperature sensors 121 (e.g., the unit of the plurality of memory areas) may include an entire memory device, an entire memory cell array, a block, a super block, a plurality of word lines, a single word line, a page, etc.

According to one or more embodiments, the first time point t₁ may be a time point at which a first resource management operation, such as reclaim or garbage collection, is performed. According to another embodiment, the first time point t₁ may be a time point at which a write, read, or erase operation is performed on some of the plurality of memory areas of the nonvolatile memory device 12. According to another embodiment, the memory controller 11 may transmit a temperature measurement command cm1 to the nonvolatile memory device 12, and the control logic 122 may receive the temperature measurement command cm1 and transmit the temperature measurement command cm1 to the one or more temperature sensors 121. In response to the temperature measurement command cm1, the one or more temperature sensors 121 may start periodic temperature measurement at the first time point t₁ (operation (a)). That is, at a time point at which the first resource management operation is performed, at a time point at which the write, read, or erase operation is performed on at least one memory area from among the plurality of memory areas, or at a time point at which the temperature measurement command cm1 is received, the one or more temperature sensors 121 may start the temperature measurement with respect to the plurality of memory areas (operation (a)).

According to one or more embodiments, the temperature measurement command cm1 may correspond to a get feature command defined in the NVMe standard specifications. In detail, the command cm1 for requesting a start of temperature measurement may be generated by using a “reserved” field(s) in a get feature command format. According to another embodiment, the memory controller 11 may generate a separate command cm1 for requesting a start of temperature measurement and transmit the command cm1 to the nonvolatile memory device 12.

A measurement period Tₘ of the one or more temperature sensors 121 may be predetermined. According to one or more embodiments, the measurement period Tₘ of the one or more temperature sensors 121 may be predetermined by taking into account the period of the resource management operation, such as reclaim, garbage collection, etc. For example, when the period of the reclaim operation is a day, the measurement period Tₘ may be 4 hours. The measurement period Tₘ of the one or more temperature sensors 121 may vary according to cases. For example, when the period of the resource management operation is changed, the nonvolatile memory device 12 may receive, from the memory controller 11, a command for requesting a change of the temperature measurement period Tₘ. According to one or more embodiments, the command for requesting a change of the temperature measurement period Tₘ may correspond to a set feature command defined in the NVMe standard specifications. In detail, the command for requesting a change of the temperature measurement period Tₘ may be generated by using a “reserved” field(s) in a set feature command format. According to another embodiment, the memory controller 11 may generate a separate command for requesting a change of the temperature measurement period Tₘ and may transmit the command to the nonvolatile memory device 12. The nonvolatile memory device 12 may change and/or update the temperature measurement period Tₘ of the one or more temperature sensors 121 in response to the command for requesting a change of the temperature measurement period Tₘ and may report the completion of the change of the period to the memory controller 11.

The second time point t₂ may be a time point elapsed from the first time point t₁ by a predetermined period of time and may be the time point before a time point t₃ at which a next resource management operation (or a second resource management operation), such as next reclaim, next garbage collection, etc., is performed. For example, the second time point t₂ may be before the time point t₃ at which the second resource management operation is expected to be performed, wherein a difference between the second time point t₂ and the time point t₃ may correspond to a predetermined time period THR. Based on this configuration, the memory controller (e.g., 11 in FIG. 1) may bring forward, delay, or maintain the time point t₃ of the second resource management operation, by taking into account a temperature change of the nonvolatile memory device 12 before the second resource management operation is started.

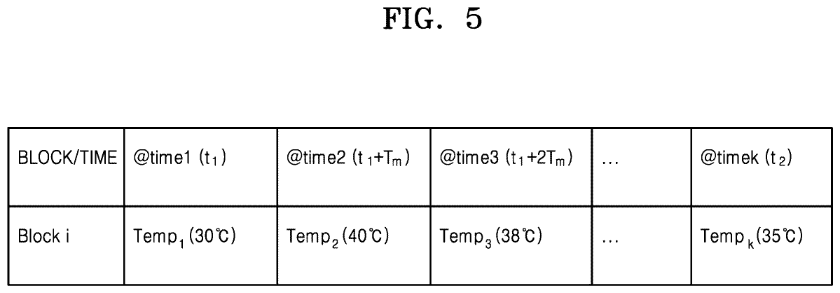

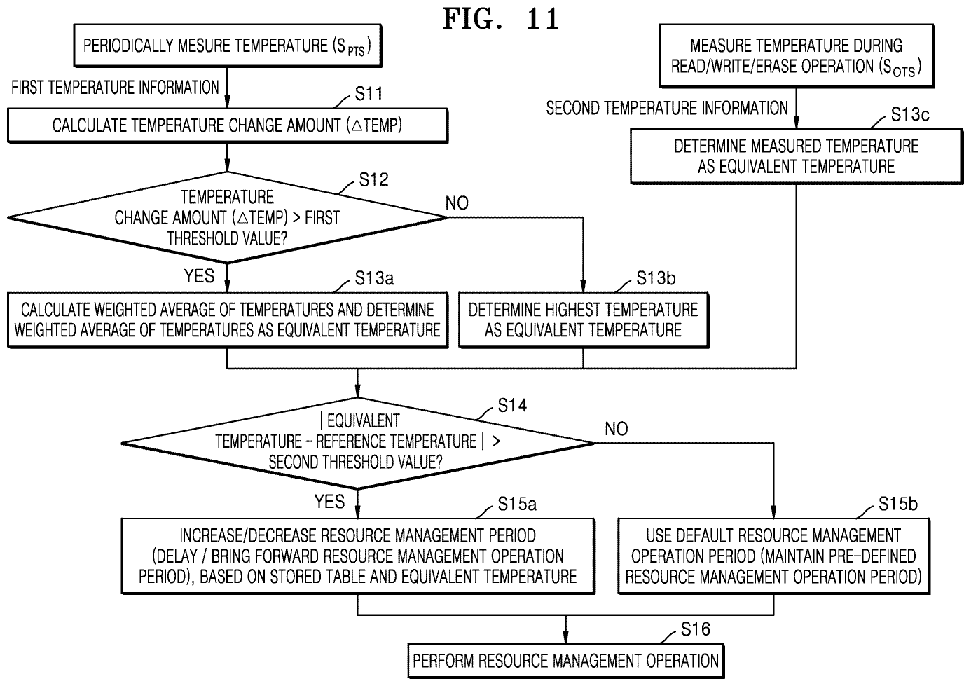

FIG. 5 illustrates an example of the first temperature information generated by the PTS method of the one or more temperature sensors 121 of FIG. 3. In detail, the temperature information illustrated in FIG. 5 may indicate the first temperature information generated when the one or more temperature sensors 121 periodically measure the temperature of at least one memory area (e.g., a Block i (i is a natural number that is 1 or greater)) from among the plurality of memory areas by using the method of FIG. 4. For example, temperature Temp₁ of the Block i at the first time point t₁ may be measured to be 30° C., and temperature Temps of the Block i at the second time point t₂ may be measured to be 35° C. As described below, the resource management module 112 of the memory controller 11 may determine a change amount of the temperature Temp and a highest temperature of the Block i, based on the first temperature information, and may bring forward, delay, or maintain the time point t₃ of the second resource management operation, based on at least one of the change amount of the temperature and the highest temperature. This aspect will be described later with reference to FIG. 11.

Referring to FIGS. 3 and 4 again, the generated first temperature information may be stored in a storage (for example, one or more registers) of the one or more temperature sensors 121 or an additional storage. For example, the one or more temperature sensors 121 may transmit the first temperature information to the additional storage, for example, the buffer 122a of the control logic 122 or the SRAM, and the additional storage may store the first temperature information. Hereinafter, for convenience of explanation, it is assumed that the first temperature information is stored in the buffer 122a of the control logic 122.

According to one or more embodiments, after the nonvolatile memory device 12 obtains the first temperature information via the one or more temperature sensors 121, or whenever the nonvolatile memory device 12 measures the temperature with respect to the plurality of memory areas, the nonvolatile memory device 12 may transmit the temperature information to the memory controller 11 (operation (c)). According to another embodiment, when the nonvolatile memory device 12 receives, from the memory controller 11, a command for requesting the first temperature information, the nonvolatile memory device 12 may transmit the first temperature information to the memory controller 11 (operation (c)). For example, between the first time point t₁ and the second time point t₂, for example, after the second time point t₂ and before the expected time point t₃ of the second resource management operation, the memory controller 11 may transmit, to the nonvolatile memory device 12, a first command REQ_TEMP for requesting the first temperature information.

According to one or more embodiments, the first command REQ_TEMP may be a command for requesting a report of temperature information (for example, the first temperature information) stored in the buffer 122a and may correspond to a get feature command defined in the NVMe standard specifications. In detail, the command for requesting the temperature information may be generated by using a “reserved” field(s) in a get feature command format. According to another embodiment, the memory controller 11 may generate the additional first command REQ_TEMP for requesting the first temperature information and may transmit the first command REQ_TEMP to the nonvolatile memory device 12. According to another embodiment, the memory controller 11 may transmit a single command for requesting both of the temperature information and the temperature measurement, rather than separately transmitting the temperature measurement command cm1 and the command REQ_TEMP for requesting the temperature information.

The memory controller interface 127 of the nonvolatile memory device 12 may receive the first command REQ_TEMP from the memory controller 11 and transmit the first command REQ_TEMP to the control logic 122. In response to the first command REQ_TEMP, the control logic 122 may transmit the temperature information GET_TEMP indicating the first temperature information stored in the buffer 122a to the memory controller 11 through the memory controller interface 127. According to one or more embodiments, the first temperature information may be transmitted to the memory controller 11 through a data signal (DQ) pin or a command address (CA) pin of the nonvolatile memory device 12.

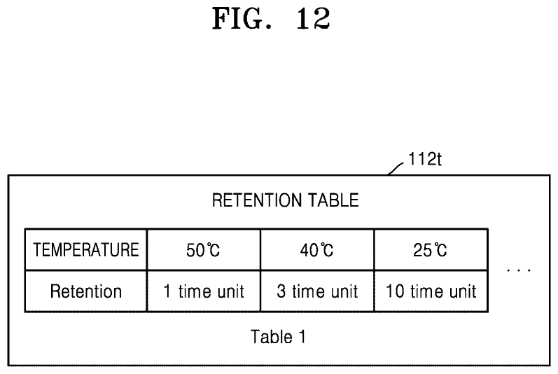

The resource management module 112 of the nonvolatile memory device 12 may obtain the first temperature information (operation (c)). Next, an equivalent temperature calculator 112a of the resource management module 112 may determine, from the first temperature information, a temperature change amount and the highest temperature of at least one memory area during a time section between the first time point t₁ and the second time point t₂, and may determine an equivalent temperature, based on at least one of the temperature change amount and the highest temperature (operation (d)). Next, a period adjustor 112b of the resource management module 112 may adjust the time point t₃ of the next resource management operation on at least one memory area, based on the equivalent temperature (operation (e)). According to one or more embodiments, the resource management module 112 may store a table (e.g., 112t in FIG. 12) with respect to data retention according to the temperature, and the period adjustor 112b of the resource management module 112 may adjust the time point t₃ of the next resource management operation by referring to the equivalent temperature and the stored table 112t. Examples of a method, performed by the resource management module 112, of determining the equivalent temperature, and an operation, performed by the resource management module 112, of adjusting the period of the next resource management operation will described in detail later with reference to FIGS. 11 and 12.

Next, a resource management performer 112c of the resource management module112 may perform the resource management operation, such as reclaim, garbage collection, trim, or the like, at the adjusted time point t₃.

According to one or more embodiments, it is described that the temperature measurement unit and a resource management unit are the same (e.g., the unit of the memory area). However, the disclosure is not limited thereto. That is, the temperature measurement unit may be different from the resource management unit. For example, temperature measurement may be performed on the entire nonvolatile memory device 12, but resource management may be performed for each block of the nonvolatile memory device 12.

According to another embodiment, when a certain time period elapses from the second time point t₂, the first temperature information may be initialized (operation (f)). For example, when the first temperature information is stored in the buffer 122a, the buffer 122a may be configured to initialize the first temperature information after a certain time period. Based on this configuration, a storage space of the buffer 122a may be managed.

Hereinafter, referring to FIGS. 3 and 6 to 9, the method, performed by the one or more temperature sensors 121, of measuring the temperature of the nonvolatile memory device 12 when a read, write, or erase operation is performed on the nonvolatile memory device 12, is described. Hereinafter, the same descriptions between the embodiments may be omitted.

First, referring to FIGS. 3 and 6, the memory controller 11 may transmit, to the control logic 122 of the nonvolatile memory device 12, a temperature measurement command cm2 together with a write, read, or erase operation command CMD (operation S1). In this case, the temperature measurement command cm2 may correspond to a get feature command defined in the NVMe standard specifications. In detail, the command cm2 for requesting a start of temperature measurement may be generated by using a “reserved” field(s) in a get feature command format. According to another embodiment, the memory controller 11 may generate a separate command cm2 for requesting a start of temperature measurement and transmit the command cm2 to the nonvolatile memory device 12 (operation S1). According to another embodiment, the memory controller 11 may transmit the temperature measurement command (e.g., period temperature measurement command) cm1 and the temperature measurement command cm2 together with the write, read, or erase operation command CMD to the control logic 122 of the nonvolatile memory device 12.

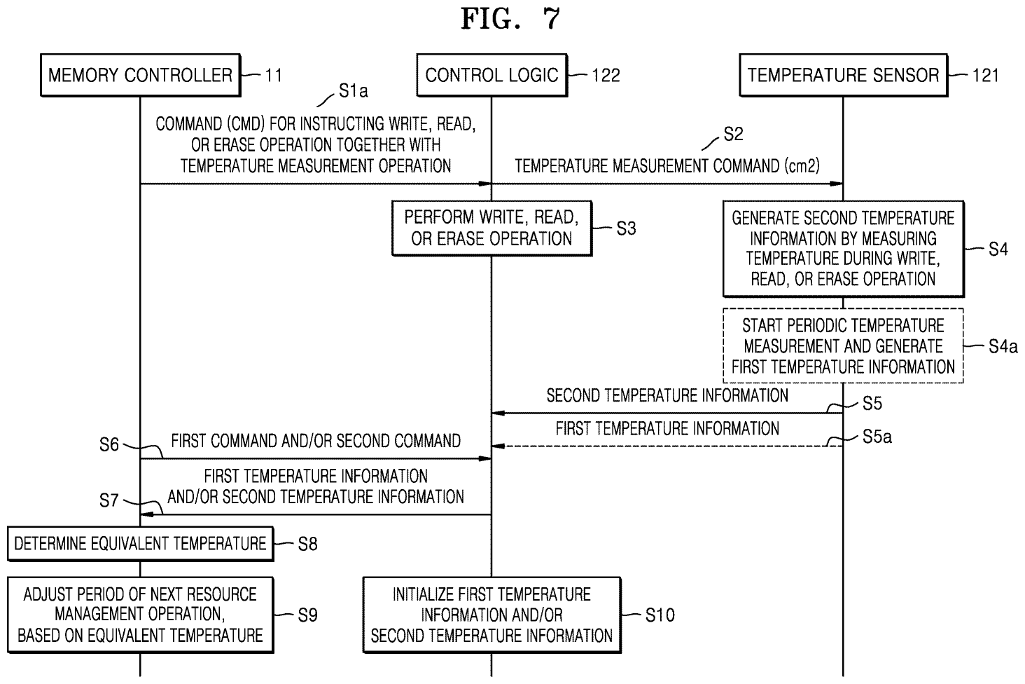

However, unlike the embodiment of FIGS. 3 and 6, in which the write, read, or erase operation command CMD is separately transmitted from the temperature measurement command cm2, according to another embodiment illustrated in FIG. 7, the memory controller 11 may transmit a single command CMD for instructing a temperature measurement operation together with a write, read, or erase operation (operation S1a). In this case, the memory controller 11 may instruct the temperature measurement operation by using a temperature measurement flag bit in the command CMD of the write, read, or erase operation, etc. For example, 1B or 1 bit of a z-address bit space in a read command may be used as the temperature measurement flag bit. In detail, when temperature measurement is not required when the write, read, or erase operation is commanded, a command having the temperature measurement flag bit of a first bit value (for example, bit “0”) may be transmitted to the nonvolatile memory device 12. When temperature measurement is required when the write, read, or erase operation is commanded, a command having the temperature measurement flag bit of a second bit value (for example, bit “1”) may be transmitted to the nonvolatile memory device 12.

Next, referring to FIGS. 3, 6, and 7, the nonvolatile memory device 12 may transmit the command(s) to the control logic 122 through the memory controller interface 127. The control logic 122 may transmit the temperature measurement command cm2 to the one or more temperature sensors 121, in response to the temperature measurement command of the memory controller 11 (operation S2). Also, the control logic 122 of the nonvolatile memory device 12 may perform a corresponding write, read, or erase operation, in response to the command CMD for instructing the write, read, or erase operation (operation S3).

The one or more temperature sensors 121 may generate second temperature information by measuring the temperature of the plurality of memory areas while the write, read, or erase operation is being performed, in response to the temperature measurement command cm2 (operation S4). According to one or more embodiments, when a write, read, or erase operation is performed on a first memory area from among the plurality of memory areas, the one or more temperature sensors 121 may generate the second temperature information by measuring the temperature of the first memory area while the corresponding operation is being performed on the first memory area (operation S4).

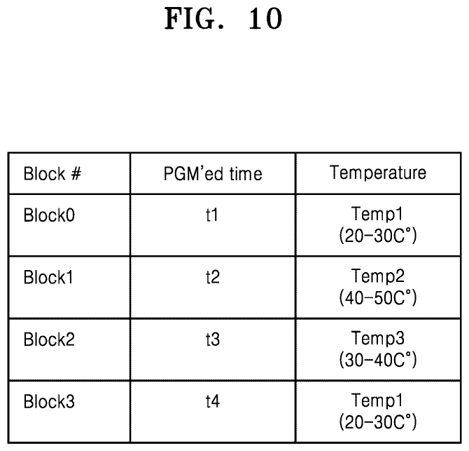

FIG. 10 illustrates an example of the second temperature information generated by a method of measuring the temperature while a write, read, or erase operations is being performed. In detail, the temperature information illustrated in FIG. 10 indicates the second temperature information generated by the one or more temperature sensors 121, according to the method of FIGS. 6 to 9, while a program (e.g., write) operation is being performed on the plurality of memory areas. For example, a Block0 may be programmed at the first time point t₁, and the temperature of the Block0 may be 25° C. during the program operation. A Block1 may be programmed at the second time point t₂, and the temperature of the Block1 may be 45° C. during the program operation. According to another embodiment, the temperatures of the blocks may be recorded to be in a certain range as illustrated in FIG. 10. For example, a Block0 may be programmed at the first time point t₁, and a temperature range of the Block0 may be Temp₁ (20-30° C.) during the program operation. A Block1 may be programmed at the second time point t₂, and a temperature range of the Block1 may be Temp₂ (40-50° C.) during the program operation. As described below, the resource management module 112 of the memory controller 11 may, based on this second temperature information, bring forward, delay, or maintain the period of a next resource management operation. This aspect will be described in detail later with reference to FIG. 11.

Referring to FIGS. 3, 6, and 7 again, the generated second temperature information may be stored in one or more storages (for example, one or more registers) of the one or more temperature sensors 121 or an additional storage. For example, the one or more temperature sensors 121 may transmit the second temperature information to the additional storage, for example, the buffer 122a of the control logic 122 or the SRAM (operation S5), and the storage may store the second temperature information. Hereinafter, for convenience of explanation, it is assumed that the second temperature information is stored in the buffer 122a of the control logic 122.

According to another embodiment, in response to the temperature measurement command cm2, the one or more temperature sensors 121 may start periodic temperature measurement on the plurality of memory areas and generate the first temperature information (operation S4a). According to another embodiment, when a write, read, or erase operation is performed on a first memory area from among the plurality of memory areas, the one or more temperature sensors 121 may start the periodic temperature measurement on the first memory area and generate the first temperature information (operation S4a). The generated first temperature information may be transmitted to the buffer 122a of the control logic 122 (operation S5a), and the buffer 122a may store the first temperature information.

Some or all of operations S2, S3, S4, and S4a may be simultaneously performed or may be sequentially performed.

Next, when the control logic 122 receives a first command and/or a second command for requesting the first temperature information and/or the second temperature information from the memory controller 11 (operation S6), the first temperature information and/or the second temperature information stored in the buffer 122a may be transmitted to the memory controller 11 (operation S7). For example, the memory controller 11 may transmit a second command REQ_TEMP for requesting the second temperature information to the nonvolatile memory device 12 before the period of an expected next resource management operation period (operation S7). In detail, the memory controller interface 127 of the nonvolatile memory device 12 may receive the second command REQ_TEMP from the memory controller 11 and may transmit the second command REQ_TEMP to the control logic 122.

According to one or more embodiments, the second command REQ_TEMP may be a command for requesting the report of the second temperature information stored in the buffer 122a and may correspond to a get feature command defined in the NVMe standard specifications. In detail, the command for requesting the second temperature information may be generated by using a “reserved” field(s) in a get feature command format. According to another embodiment, the memory controller 11 may generate the additional second command REQ_TEMP for requesting the second temperature information and may transmit the second command REQ_TEMP to the nonvolatile memory device 12.

Next, in response to the second command REQ_TEMP, the control logic 122 may transmit the second temperature information GET_TEMP stored in the buffer 122a to the memory controller 11 through the memory controller interface 127 (operation S7). According to one or more embodiments, the second temperature information may be transmitted to the memory controller 11 through a DQ pin or a CA pin of the nonvolatile memory device 12.

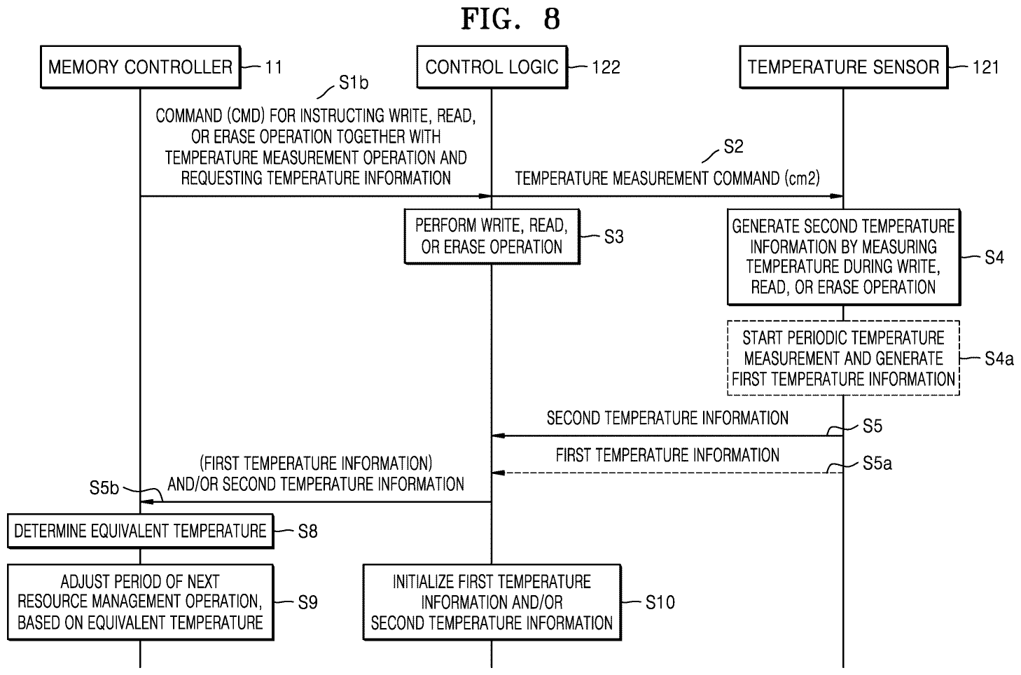

According to another embodiment, rather than separately transmitting the second temperature measurement command cm2 and the second command REQ_TEMP for requesting the second temperature information, the memory controller 11 may transmit a single command for requesting both of the second temperature measurement and the second temperature information as illustrated in FIG. 8 (operation S1b). In this case, when the nonvolatile memory device 12 obtains the second temperature information via the one or more temperature sensors 121 (operation S4), the nonvolatile memory device 12 may transmit the second temperature information to the control logic 122 and may thus transmit the second temperature information to the memory controller 11 (operation S5b).

According to another embodiment, when the one or more temperature sensors 121 perform the periodic temperature measurement in response to the temperature measurement command cm2, the memory controller 11 may transmit the first command to the control logic 122 (operation S6) and may thus obtain the first temperature information (operation S7).

Referring to FIGS. 3 and 6 to 8, the resource management module 112 of the nonvolatile memory device 12 may obtain the first temperature information and/or the second temperature information (operation S5b or S7). Next, the equivalent temperature calculator 112a of the resource management module 112 may determine, based on the first temperature information and/or the second temperature information, an equivalent temperature of the plurality of memory areas of the nonvolatile memory device 12 (operation S8). Next, the period adjustor 112b of the resource management module 112 may adjust, based on the equivalent temperature, the period of a next resource management operation on at least one memory area (for example, the first memory area) (operation S9). According to one or more embodiments, the resource management module 112 may store the table 112t with respect to the data retention according to the temperature, and the period adjustor 112b of the resource management module 112 may adjust the period of the next resource management operation by referring to the equivalent temperature and the stored table 112t. An example of a method, performed by the resource management module 112, of determining the equivalent temperature, based on the first temperature information and/or the second temperature information, will be described in detail later with reference to FIG. 11.

In general, when the storage device 10 performs a read, write, or erase operation on the first memory area, the temperature of the first memory area may change, and the temperature of one or more second memory areas adjacent to the first memory area may also change. Thus, the one or more temperature sensors 121 may measure not only the temperature of the first memory area, but also the temperature of the second memory area when the read, write, or erase operation is performed on the first memory area. To this end, in response to a command for the read, write, or erase operation with respect to the first memory area, the one or more temperature sensors 121 may start periodic temperature measurement with respect to the one or more second memory areas adjacent to the first memory area and may generate third temperature information. In addition, the one or more temperature sensors 121 may measure the temperature of the one or more second memory areas during the read, write, or erase operation with respect to the first memory area and may generate fourth temperature information. Thus, according to one or more embodiments, when the write, read, or erase operation is performed on the first memory area, the period adjustor 112b of the resource management module 112 may adjust, based on at least one of the first temperature information and the second temperature information, the period of a next resource management operation, such as reclaim, garbage collection, trim, or the like, on the first memory area and/or the one or more second memory areas adjacent to the first memory area. According to another embodiment, the period adjustor 112b of the resource management module 112 may adjust, based on the third temperature information and the fourth temperature information, the period of the next resource management operation on the one or more second memory areas adjacent to the first memory area.

Next, the resource management performer 112c of the resource management module 112 may perform the resource management operation, such as the reclaim, garbage collection, trim, or the like, at the adjusted resource management operation period.

According to another embodiment, when a certain time period elapses after the write, read, or erase operation is performed at operation S3, the first temperature information and/or the second temperature information may be initialized (operation 10). For example, when the second temperature information is stored in the buffer 122a, the buffer 122a may be configured to initialize the second temperature information after a certain time period. Based on this configuration, a storage space of the buffer 122a may be managed.

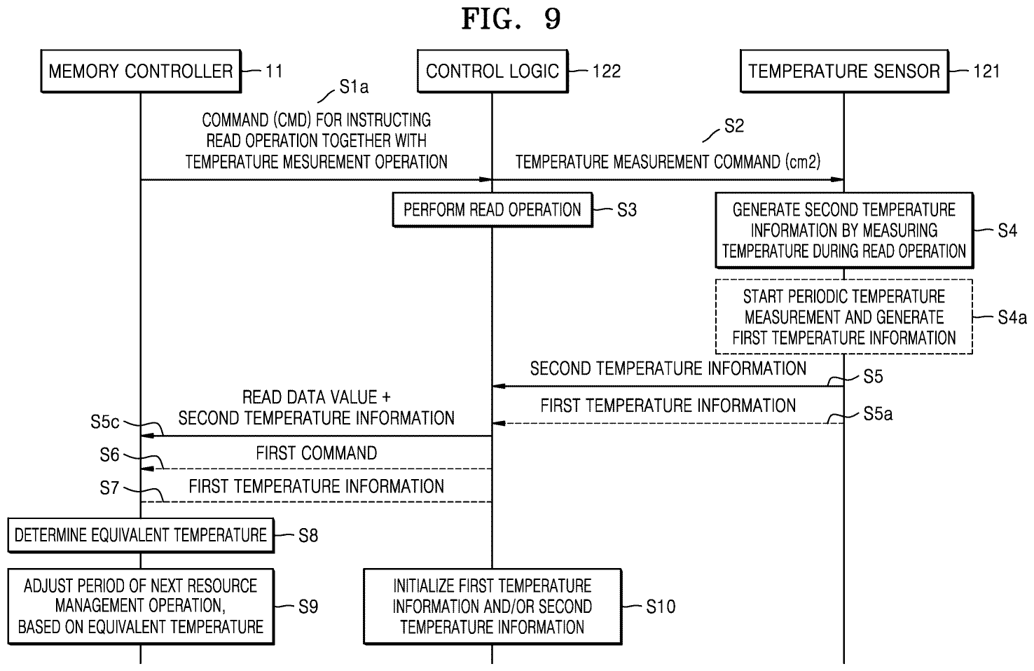

FIG. 9 shows a modified embodiment of the operating method of the storage device 10 of FIG. 7. Hereinafter, the same descriptions between the embodiments may be omitted.

The memory controller 11 may transmit one command CMD for instructing a read operation together with a temperature measurement operation (operation S1a). For example, the memory controller 11 may use 1B or 1 bit of a z-address bit space in the read command as a temperature measurement flag bit. In detail, when the temperature measurement flag bit is “0,” it may denote that the temperature measurement operation is not instructed, and when the temperature measurement flag bit is “1,” it may denote that the temperature measurement operation is instructed.

The control logic 122 may transmit a temperature measurement command cm2 to the one or more temperature sensors 121, in response to a temperature measurement instruction according to the command CMD from the memory controller 11 (operation S2). Also, the control logic 122 of the nonvolatile memory device 12 may perform the corresponding read operation in response to the command CMD for instructing the read operation (operation S3).

In response to temperature measurement command cm2, the one or more temperature sensors 121 may measure the temperature of the plurality of memory areas while the read operation is being performed and may generate second temperature information (operation S4). According to one or more embodiments, when the read operation is performed on a first memory area from among the plurality of memory areas, the one or more temperature sensors 121 may measure the temperature of the first memory area on which the read operation is performed and may generate the second temperature information (operation S4).

The one or more temperature sensors 121 may transmit the second temperature information to the buffer 122a of the control logic 122 (operation S5), and the buffer 122a may store the second temperature information.

Next, the control logic 122 may transmit the second temperature information together with read data (operation S5c). According to one or more embodiments, the control logic 122 may append the second temperature information to the read data and may transmit, to the memory controller 11, the read data to which the second temperature information is appended (operation S5c). According to another embodiment, the control logic 122 may transmit the second temperature information separately from the read data.

FIG. 11 is a flowchart of an operating method of the resource management module 112, according to one or more embodiments. In detail, FIG. 11 is a flowchart of an example of a method, performed by the resource management module 112, of determining an equivalent temperature, based on first temperature information and/or second temperature information, and adjusting the period of a resource management operation.

Referring to FIGS. 3 and 11, the one or more temperature sensors 121 may generate the first temperature information by measuring the temperature of at least one memory area from among the plurality of memory areas of the memory cell array 123 periodically between the first time point t₁ and the second time point t₂ (operation S_{PTS}).

Next, the equivalent temperature calculator 112a of the resource management module 112 may receive the first temperature information and may calculate a temperature change amount ΔTemp of the at least one memory area during the time section between the first time point t₁ and the second time t2 (operation S11).

Next, the equivalent temperature calculator 112a of the resource management module 112 may determine whether the temperature change amount ΔTemp of the at least one memory area during the time section between the first time point t₁ and the second time point t₂ is relatively great or relatively less. In detail, the equivalent temperature calculator 112a may compare the temperature change amount ΔTemp with a first threshold value (operation S12).

For example, when the first temperature information corresponds to the first temperature information illustrated in FIG. 5 and the first threshold value is 6° C., the temperature change amount ΔTemp=40° C. (Tmax)−30° C. (Tmin)=10° C.>the first threshold value (6° C.).

As described above, when the temperature change amount ΔTemp is greater than a reference temperature change amount (e.g., the first threshold value), the equivalent temperature calculator 112a may determine a weighted average of the temperatures measured during the time section between the first time point t₁ and the second time point t₂ as an equivalent temperature (operation S13a). The equivalent temperature calculator 112a may calculate the weighted average temperature according to a predetermined temperature calculation function as Equation 1 below.

$$Equivalent temperature = {{\sum }_{k = 0}}^{n} {α}_{k} \times {T}_{k} \qquad [ Equation 1 ]$$

According to one or more embodiments, when the equivalent temperature calculator 112a calculates the equivalent temperature, a greater weight may be applied to a higher temperature and a lower temperature from among the measured temperatures, and a less weight may be applied to a temperature similar to a reference temperature. Alternatively or additionally, when the equivalent temperature calculator 112a calculates the equivalent temperature, the equivalent temperature calculator 112a may calculate a weight value by taking into account a temperature duration period. For example, a greater weight may be applied to a temperature with a greater temperature duration period, and a less weight may be applied to a temperature with a less temperature duration period. In the example of FIG. 5, the weighted average temperature calculated based on the first temperature information may be 38° C., which may be determined as the equivalent temperature.

However, when the temperature change amount ΔTemp is less than or equal to the reference temperature change amount (e.g., the first threshold value), the equivalent temperature calculator 112a may determine the highest temperature of the temperatures measured during the time section between the first time point t₁ and the second time point t₂ as the equivalent temperature (operation S13b). For example, when the temperature measured during the time section between the first time point t₁ and the second time point t₂ has changed as 50° C.->49° C.->48° C.->50° C., the temperature change amount ΔTemp=50° C. (Tmax)−48° C. (Tmin)=2° C.<the first threshold value (6° C.), and thus, the highest temperature 50° C. may be determined as the equivalent temperature.

When the equivalent temperature is determined, it may be determined by the period adjustor 112b whether the difference between the equivalent temperature and the reference temperature is greater or less than a second threshold value (operation S14). Here, the reference temperature may denote a temperature which is a reference of a currently set resource management period (or a currently set period of the resource management operation). For example, the reference temperature may be 40° C., and a currently set resource management period may be set as 3 time units (that is, TU), based on 40° C. (see Table 1 of FIG. 12).

When the difference between the equivalent temperature and the reference temperature is greater than the second threshold value, the period adjustor 112b may adjust the period of the resource management operation on the memory area according to the determined equivalent temperature, with reference to the retention table 112t stored in the resource management module 112 (operation S15a). In detail, when the equivalent temperature is greater than the reference temperature by a value that is equal to or greater than the second threshold value, it may be predicted that data retention may decrease, and thus, a resource management period may be reduced (e.g., start of the next resource management operation period may be brought forward). When the equivalent temperature is less than the reference temperature by a value that is equal to or greater than the second threshold value, it may be predicted that the data retention may increase, and thus, a resource management period may be increased (e.g., the start of the next resource management operation period may be delayed).

When the difference between the equivalent temperature and the reference temperature is less than or equal to the second threshold value, the period adjustor 112b may maintain the currently set resource management operation period (for example, 3 time units) (operation S15b).

For example, when the equivalent temperature calculated based on the first temperature information illustrated in FIG. 5 is 38° C. as described above and the reference temperature is 40° C., |the equivalent temperature 38° C.−the reference temperature 40° C.|(which is 2° C.)<the second threshold value (for example, 5° C.). In this case, the period adjustor 112b may not increase or decrease the resource management operation period and may maintain the resource management operation period as 3 time units corresponding to the reference temperature 40° C.

However, when the temperature measured during the time section between the first time point t₁ and the second time point t₂ has changed as 50° C.->49° C.->48° C.->50° C., and when the equivalent temperature is 50° C. as described above and the reference temperature is 40° C., |the equivalent temperature 50° C.−the reference temperature 40° C.|(which is 10° C.)>the second threshold value (for example, 5° C.). In this case, the period adjustor 112b may reduce the resource management period to 1 time unit corresponding to the equivalent temperature 50° C., with reference to Table 1 (see e.g., FIG. 12) of the retention table 112t.

According to one or more embodiments, when the one or more temperature sensors 121 generate the second temperature information by measuring the temperature during a write, read, or erase operation, etc. (operation S_{OTS}), the equivalent temperature calculator 112a may determine the measured temperature as the equivalent temperature (operation S13c).

Next, whether the difference between the equivalent temperature and the reference temperature is greater or less than the second threshold value may be determined by the period adjustor 112b (operation S14). For example, when the temperature measured during the write, read, or erase operation, etc. is 55° C., |the equivalent temperature (55° C.)−the reference temperature (40° C.)| (which is 15° C.)>the second threshold value (for example, 5° C.). Thus, the period adjustor 112b may adjust the resource management period, based on the retention period corresponding to the equivalent temperature, which is 55° C., with reference to the retention table 112t.

Lastly, by the resource management performer 112c of the resource management module 112, a resource management operation, such as reclaim, garbage collection, trim, or the like, may be performed according to the adjusted resource management operation period.

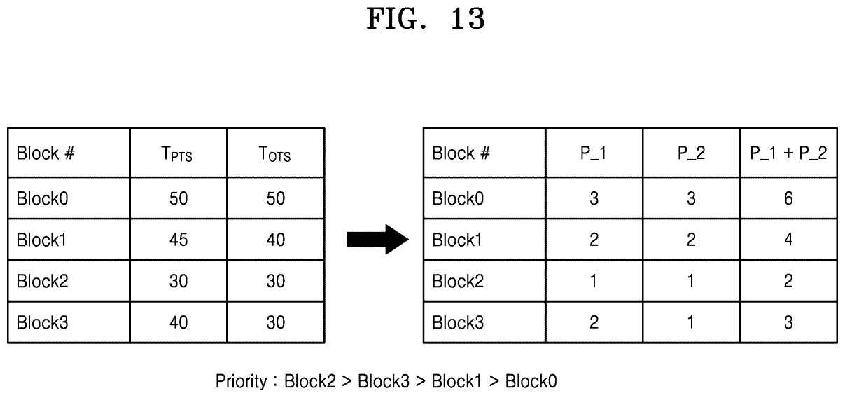

FIG. 13 is a diagram of an example in which a memory controller determines a priority order of a plurality of memory areas, according to one or more embodiments.

According to one or more embodiments, the memory controller may determine a priority order of a write, read, or erase operation with respect to a plurality of memory areas, based on first temperature information and/or second temperature information. The priority order of the write, read, or erase operation with respect to the plurality of memory areas may be used to determine an order of writing data on the plurality of memory areas, an order of reading data from the plurality of memory areas, or an order of erasing data from the plurality of memory areas. According to the priority order of the write, read, or erase operation on the plurality of memory areas, the memory controller may determine on which memory area data is to be written first, when write commands in a command queue are processed, and may determine from which memory die data stored is to be read first, when read commands in a command queue are processed. For example, when the memory controller performs a write operation on the plurality of memory areas, the memory controller may write data first on a memory area having a high priority order and write data later on a memory area having a low priority order. As another example, when the memory controller performs a read operation on the plurality of memory areas, the memory controller may read data stored in a memory area having a high priority order earlier than data stored in a memory area having a low priority order. According to another embodiment, the memory controller may determine a target area of a next read, write, or erase operation, based on the priority order.

According to one or more embodiments, the memory controller may determine a first priority order factor P_1, based on the equivalent temperature TPTs of the first temperature information of each of the plurality of memory areas measured in the time section between the first time point and the second time point. In this case, in order to delay the write, read, or erase operation on the memory area having a high temperature, it may be desirable that the first priority order factor P_1 be reduced as the equivalent temperature is decreased and that the first priority order factor P_1 be increased as the equivalent temperature is increased.

In FIG. 13, the equivalent temperature of a Block2 is the lowest as 30° C., and thus, the first priority order factor P_1 for the Block2 may be determined as a smallest value, e.g., 1. In contrast, the equivalent temperature of a Block0 is the highest as 50° C., and thus, the first priority order factor P_1 for the Block0 may be determined as a highest value, e.g., 3.

According to another embodiment, the memory controller may determine the first priority order factor P_1, based on the temperature change amount of each of the plurality of memory areas measured in the time section between the first time point and the second time point. According to another embodiment, the memory controller may determine the first priority order factor P_1, based on a highest temperature of each of the plurality of memory areas measured in the time section between the first time point and the second time point.

According to one or more embodiments, the memory controller may determine a second priority order factor P_2, based on the second temperature information Tors of a memory area measured during a write, read, or erase operation. In this case, in order to delay the write, read, or erase operation on the memory area having a high temperature, it may be desirable that the second priority order factor P_2 be reduced or kept the same as before as the second temperature is decreased and that that the second priority order factor P_2 be increased as the second temperature is increased.

In FIG. 13, the second temperature Tors of a Block2 and a Block3 is the lowest as 30° C., and thus, the second priority order factor P_2 for the Block2 and the Block3 may be determined as a smallest value, e.g., 1. In contrast, the second temperature Tors of a Block0 is the highest as 50° C., and thus, the second priority order factor P_2 for the Block0 may be determined as a highest value, e.g., 3.

According to one or more embodiments, the memory controller may determine the priority order of the plurality of memory areas, based on one of the first priority order factor P_1 and the second priority order factor P_2. According to another embodiment, the memory controller may determine the priority order of the plurality of memory areas, based on a sum of the first priority order factor P_1 and the second priority order factor P_2, as illustrated in FIG. 13.

The memory controller may determine a higher priority order of a write, read, or erase operation on a memory area, with respect to which the sum of the first priority order factor P_1 and the second priority order factor P_2 is small. That is, when a sum 2 of the first priority order factor P_1 and the second priority order factor P_2 with respect to a first memory area (for example, the Block2) from among the plurality of memory areas is less than a sum 4 of the first priority order factor P_1 and the second priority order factor P_2 with respect to a second memory area (for example, the Block1) from among the plurality of memory areas, the memory controller may determine the write, read, or erase operation on the first memory area to have a higher priority order than the write, read, or erase operation on the second memory area. Based on this configuration, the write, read, or erase operation on the memory area having a high temperature may be delayed, to minimize performance deterioration.

According to another embodiment, the memory controller may perform, based on the first temperature information and/or the second temperature information, one or more of wear leveling, bad block management, write or read level management, etc. on the plurality of memory areas. For example, the memory controller may adjust at least one of a level of a next write operation, a next read operation, and a next erase operation on the first memory area, based on at least one of the first temperature information and the second temperature information.

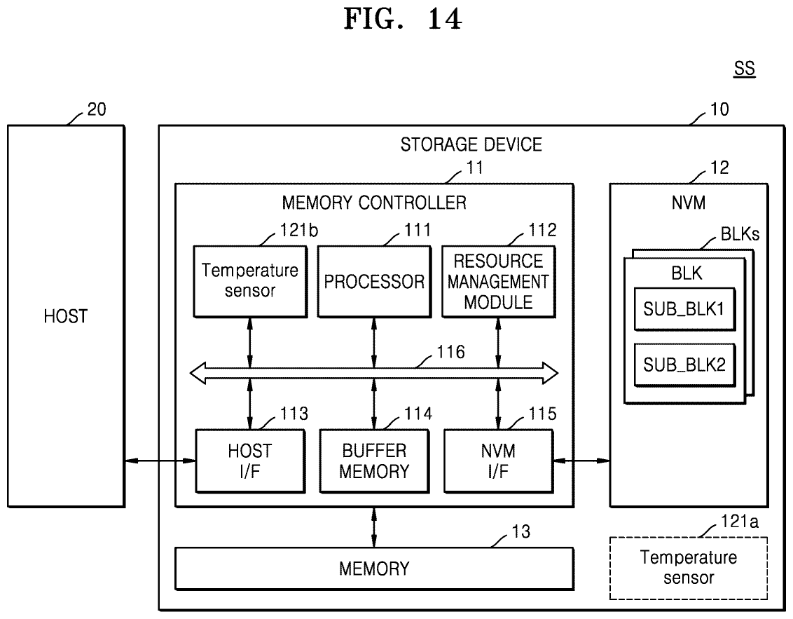

FIG. 14 is a block diagram of a storage system according to one or more other embodiments. FIG. 14 illustrates a modified embodiment of the storage system of FIG. 1. Hereinafter, the same descriptions between the embodiments may be omitted.

Referring to FIG. 14, the memory controller 11 may include a temperature sensor 121b. According to an alternative or additional embodiment, the storage device 10 may include a temperature sensor 121a. Unlike FIG. 1, in which the one or more temperature sensors 121 in the nonvolatile memory device 12 are configured to measure the temperature of the nonvolatile memory device 12 or one or more memory areas of a memory cell array of the nonvolatile memory device 12, the temperature sensor 121a and/or the temperature sensor 121b may measure the temperature of the nonvolatile memory device 12. A method used by the temperature sensor 121a and/or the temperature sensor 121b to measure the temperature may include the PTS method as in FIG. 4 and/or the method of measuring the temperature during a write, read, or erase (R/W/E) operation.

The temperature measured by the temperature sensor 121a and/or the temperature sensor 121b may be stored in an additional storage area (for example, a register of the temperature sensor 121a and/or a register of the temperature sensor 121b). The memory controller 11 may obtain temperature information by accessing the additional storage area.

The resource management module 112 may determine and/or adjust the period of reclaim, garbage collection, and trim operations, etc. on the nonvolatile memory device 12, based on the temperature of the nonvolatile memory device 12 measured by the temperature sensor 121a and/or the temperature sensor 121b, and thus, may increase, maintain, or reduce the frequency of the reclaim, garbage collection, and trim operations, etc. In detail, the resource management module 112 may determine the equivalent temperature based on the first temperature information and the second temperature information as shown in the method illustrated in FIG. 11 and may adjust the resource management operation period.

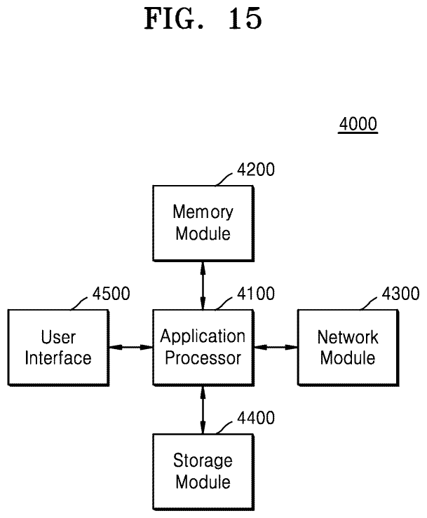

FIG. 15 is a block diagram of a user system 4000 in which a storage device is implemented, according to one or more embodiments.

Referring to FIG. 15, the user system 4000 may include an application processor 4100, a memory module 4200, a network module 4300, a storage module 4400, and a user interface 4500.

The application processor 4100 may drive components included in the user system 4000, an operating system (OS), a user program, or the like. For example, the application processor 4100 may include controllers configured to control the components included in the user system 4000, interfaces, graphic engines, etc. The application processor 4100 may be provided as a system-on-chip (SoC).

The memory module 4200 may operate as a main memory, an operating memory, a buffer memory, or a cache memory in the user system 4000. The memory module 4200 may include a volatile random-access memory, such as a DRAM, a synchronous DRAM (SDRAM), a double data rate (DDR) SDRAM, a DDR2 SDRAM, a DDR3 SDRAM, a lower power DDR (LPDDR) SDRAM, an LPDDR2 SDRAM, an LPDDR3 SDRAM, etc., or a nonvolatile random-access memory, such as a PRAM, a resistive random-access memory (ReRAM), a magnetic random-access memory (MRAM), a ferroelectric random-access memory (FRAM), etc. For example, the application processor 4100 and the memory module 4200 may be packaged based on a package on package (POP) scheme and provided as one semiconductor package.

The network module 4300 may perform communication with an external device(s). For example, the network module 4300 may support wireless communication, such as code division multiple access (CDMA), a global system for mobile communication (GSM), wideband CDMA (WCDMA), CDMA-2000, time division multiple access (TDMA), long term evolution (LTE), Wimax, a wide local area network (WLAN), ultra wideband (UWB), Bluetooth, WiFi, etc. For example, the network module 4300 may be included in the application processor 4100.

The storage module 4400 may store data. For example, the storage module 4400 may store data received from the application processor 4100. Alternatively, the storage module 4400 may transmit data stored in the storage module 4400 to the application processor 4100. For example, the storage module 4400 may be realized as a nonvolatile semiconductor memory device, such as a PRAM, an MRAM, an RRAM, a NAND flash, an NOR flash, a three-dimensional structure NAND flash, etc. For example, the storage module 4400 may be provided as a removable drive such as a memory card, an external drive, etc. of the user system 4000.

The storage module 4400 may include a plurality of nonvolatile memory devices and may operate in the same manner as the storage device 10 described with reference to FIGS. 1 to 4, 5 to 9, and 11.

The user interface 4500 may include an interface(s) configured to input data or an instruction to the application processor 4100 and/or an interface(s) configured to output data to an external device. For example, the user interface 4500 may include user input interfaces, such as a keyboard, a keypad, a button, a touch panel, a touch screen, a touch pad, a touch ball, a camera, a microphone, a gyroscope sensor, a vibration sensor, a piezoelectric device, etc. The user interface 4500 may include user output interfaces, such as a liquid crystal display (LCD), an organic light-emitting diode (OLED) display apparatus, an active matrix OLED (AMOLED) display apparatus, a light-emitting diode (LED), a speaker, a monitor, etc.

At least one of the components, elements, modules or units (collectively “components” in this paragraph) represented by a block in the drawings, may be embodied as various numbers of hardware, software and/or firmware structures that execute respective functions described above, according to an example embodiment. For example, at least one of these components may use a direct circuit structure, such as a memory, a processor, a logic circuit, a look-up table, etc. that may execute the respective functions through controls of one or more microprocessors or other control apparatuses. Also, at least one of these components may be specifically embodied by a module, a program, or a part of code, which contains one or more executable instructions for performing specified logic functions, and executed by one or more microprocessors or other control apparatuses. Further, at least one of these components may include or may be implemented by a processor such as a central processing unit (CPU) that performs the respective functions, a microprocessor, or the like. Two or more of these components may be combined into one single component which performs all operations or functions of the combined two or more components. Also, at least part of functions of at least one of these components may be performed by another of these components. Further, although a bus is not illustrated in the above block diagrams, communication between the components may be performed through the bus. Functional aspects of the above example embodiments may be implemented in algorithms that execute on one or more processors. Furthermore, the components represented by a block or processing steps may employ any number of related art techniques for electronics configuration, signal processing and/or control, data processing and the like.

While the disclosure has been particularly shown and described with reference to example embodiments thereof, it will be understood that various changes in form and details may be made therein without departing from the spirit and scope of the following claims and their equivalents.

What is claimed is:

1. A storage device comprising:
a nonvolatile memory device comprising:
a plurality of memory areas, each memory area comprising one or more memory cells;
one or more temperature sensors configured to generate first temperature information by periodically measuring, in a time period between a first time point and a second time point, at least one temperature of at least one memory area from among the plurality of memory areas; and
a buffer configured to store the first temperature information; and
a memory controller configured to:
obtain the first temperature information by transmitting, to the nonvolatile memory device, a first command for requesting the first temperature information;
determine an equivalent temperature, based on at least one of a temperature change amount and a highest temperature of the at least one memory area measured in the time period between the first time point and the second time point; and
adjust, based on the equivalent temperature, at least one of a period of a reclaim operation, a period of a garbage collection operation, and a period of a trim operation on the at least one memory area.

2. The storage device of claim 1, wherein the memory controller is further configured to:
transmit, to the nonvolatile memory device, a command for a write operation, a read operation, or an erase operation and a temperature measurement command; or
transmit, to the nonvolatile memory device, a command for instructing the write operation, the read operation, or the erase operation together with a temperature measurement operation, and
wherein the nonvolatile memory device is further configured to:
perform the write operation, the read operation, or the erase operation in response to the command for the write operation, the read operation, or the erase operation; and
generate, via the one or more temperature sensors, second temperature information by measuring temperatures of the plurality of memory areas, while the write operation, the read operation, or the erase operation is being performed.

3. The storage device of claim 2, wherein the memory controller is further configured to obtain the second temperature information by transmitting a second command for requesting the second temperature information to the nonvolatile memory device, and adjust, based on the second temperature information, the at least one of the period of the reclaim operation, the period of the garbage collection operation, and the period of the trim operation on each memory area of the plurality of memory areas.

4. The storage device of claim 2, wherein, based on the command for the read operation transmitted from the memory controller to the nonvolatile memory device, the nonvolatile memory device is further configured to transmit the second temperature information together with read data.

5. The storage device of claim 2, wherein the first time point is a time point at which the write operation, the read operation, or the erase operation is performed on a first memory area from among the plurality of memory areas, and
wherein the memory controller is further configured to adjust the at least one of the period of the reclaim operation, the period of the garbage collection operation, and the period of the trim operation on the first memory area, based on at least one of the first temperature information and the second temperature information.

6. The storage device of claim 5, wherein the memory controller is further configured to adjust, based on the second temperature information, the at least one of the period of the reclaim operation, the period of the garbage collection operation, and the period of the trim operation on a second memory area adjacent to the first memory area.

7. The storage device of claim 1, wherein the memory controller is further configured to determine, based on the first temperature information, a priority order of a write operation, a read operation, or erase operation on the plurality of memory areas of the nonvolatile memory device.

8. The storage device of claim 1, wherein the buffer is further configured to initialize the first temperature information based on an elapse of a certain time period from the second time point.

9. The storage device of claim 1, wherein the memory controller is further configured to store a table with respect to data retention in the nonvolatile memory device, based on a temperature, and
wherein the memory controller is further configured to:
compare the temperature change amount of the at least one memory area measured in the time period between the first time point and the second time point with a threshold value;
based on the temperature change amount being greater than the threshold value, determine a weighted average of the at least one temperature of the at least one memory area measured in the time period between the first time point and the second time point as the equivalent temperature, according to a predetermined temperature calculation function;
based on the temperature change amount being equal to or less than the threshold value, determine the highest temperature of the at least one memory area measured in the time period between the first time point and the second time point as the equivalent temperature; and
determine the at least one of the period of the reclaim operation, the period of the garbage collection operation, and the period of the trim operation on the at least one memory area, according to the determined equivalent temperature, by referring to the stored table.

10. The storage device of claim 1, wherein the nonvolatile memory device is further configured to receive, from the memory controller, a third command for requesting a change of a temperature measurement period, and update, in response to the received third command, the temperature measurement period.

11. An operating method of a storage device comprising a nonvolatile memory device and a memory controller, the nonvolatile memory device comprising a plurality of memory areas and at least one temperature sensor, the operating method comprising:
generating, by the at least one temperature sensor, first temperature information by periodically measuring, in a time period between a first time point and a second time point, at least one temperature of at least one memory area from among the plurality of memory areas;
storing the first temperature information in a buffer of the nonvolatile memory device;
transmitting, by the memory controller, a first command for requesting the first temperature information to the nonvolatile memory device;
in response to the first command received from the memory controller, transmitting, by the nonvolatile memory device, the first temperature information to the memory controller;
comparing, by the memory controller, a temperature change amount of the at least one memory area in the time period between the first time point and the second time point with a threshold value;
based on the temperature change amount being greater than the threshold value, determining a weighted average of the at least one temperature of the at least one memory area measured in the time period between the first time point and the second time point as an equivalent temperature, according to a predetermined temperature calculation function;
based on the temperature change amount being equal to or less than the threshold value, determining a highest temperature of the at least one memory area measured in the time period between the first time point and the second time point as the equivalent temperature; and
adjusting, by the memory controller, at least one of a period of a reclaim operation, a period of a garbage collection operation, and a period of a trim operation on the at least one memory area, based on the equivalent temperature.

12. The operating method of claim 11, further comprising:
transmitting, by the memory controller, a command for instructing a write operation, a read operation, or an erase operation together with a temperature measurement operation, to the nonvolatile memory device;
performing, by the nonvolatile memory device, the write operation, the read operation, or the erase operation on a first memory area from among the plurality of memory areas, in response to the command for instructing the write operation, the read operation, or the erase operation, and generating, by the at least one temperature sensor, second temperature information by measuring a temperature of the first memory area while the write operation, the read operation, or the erase operation is being performed on the first memory area;
transmitting, by the memory controller, a second command for requesting the second temperature information to the nonvolatile memory device; and
transmitting, by the nonvolatile memory device, the second temperature information to the memory controller, in response to the second command.

13. The operating method of claim 12, further comprising adjusting, by the memory controller, the at least one of the period of the reclaim operation, the period of the garbage collection operation, and the period of the trim operation on the first memory area, based on at least one of the first temperature information and the second temperature information.

14. The operating method of claim 13, further comprising adjusting, by the memory controller, the at least one of the period of the reclaim operation, the period of the garbage collection operation, and the period of the trim operation on a second memory area adjacent to the first memory area, based on at least one of the first temperature information and the second temperature information.

15. The operating method of claim 12, wherein the command for instructing the write operation, the read operation, or the erase operation requests the second temperature information as well as instructs the temperature measurement operation,
wherein the operating method further comprising generating, by the at least one temperature sensor, the second temperature information in response to the command for instructing the write operation, the read operation, or the erase operation and transmitting the generated second temperature information to the memory controller.

16. The operating method of claim 12, wherein the first time point is a time point at which the write operation, the read operation, or the erase operation is performed on the first memory area in response to the command for instructing the write operation, the read operation, or the erase operation.

17. An operating method of a storage device comprising a nonvolatile memory device and a memory controller, the nonvolatile memory device comprising a plurality of memory areas and at least one temperature sensor, the operating method comprising:
transmitting, by the memory controller, a command for instructing a write operation, a read operation, or an erase operation together with a temperature measurement operation, to the nonvolatile memory device;
in response to the command for instructing the write operation, the read operation, or the erase operation, performing, by the nonvolatile memory device, the write operation, the read operation, or the erase operation on a first memory area from among the plurality of memory areas;
generating, by the at least one temperature sensor, first temperature information by starting periodic temperature measurement on the first memory area; and
generating, by the at least one temperature sensor, second temperature information by measuring a temperature of the first memory area while the write operation, the read operation, or the erase operation is performed on the first memory area.

18. The operating method of claim 17, further comprising:
transmitting, by the memory controller, a temperature check command to the nonvolatile memory device;
in response to the temperature check command, transmitting, by the nonvolatile memory device, at least one of the first temperature information and the second temperature information to the memory controller; and
adjusting, by the memory controller, at least one of a period of a reclaim operation, a period of a garbage collection operation, and a period of a trim operation on the first memory area, based on at least one of the first temperature information and the second temperature information.

19. The operating method of claim 18, further comprising adjusting, by the memory controller, at least one of a level of a next write operation, a next read operation, and a next erase operation on the first memory area, based on at least one of the first temperature information and the second temperature information.

20. The operating method of claim 17, further comprising, in response to the command for instructing the write operation, the read operation, or the erase operation:
generating, by the at least one temperature sensor, third temperature information by starting periodic temperature measurement on a second memory area adjacent to the first memory area;
generating, by the at least one temperature sensor, fourth temperature information by measuring a temperature of the second memory area while the write operation, the read operation, or the erase operation is being performed on the first memory area;
transmitting, by the nonvolatile memory device, the third temperature information and the fourth temperature information to the memory controller; and
adjusting, by the memory controller, at least one of a period of a reclaim operation, a period of a garbage collection operation, and a period of a trim operation on the second memory area, based on at least one of the third temperature information and the fourth temperature information.
